(19) United States
(12) Patent Application Publication
(10) Pub. No.: US 2017/0030958 A1
(43) Pub. Date: Feb. 2, 2017

(54) TRANSFORMER PARAMETER ESTIMATION USING TERMINAL MEASUREMENTS

(71) Applicant: ABB Schweiz AG, Baden (CH)

(72) Inventors: Ziang Zhang, Vestal, NY (US); Ning Kang, Morrisville, NC (US); Mirrasoul Mousavi, Cary, NC (US)

(21) Appl. No.: 15/294,238

(22) Filed: Oct. 14, 2016

Related U.S. Application Data
(63) Continuation of application No. PCT/US15/25076, filed on Apr. 9, 2015.
(60) Provisional application No. 61/979,677, filed on Apr. 15, 2014.

(51) Int. Cl. G01R 31/02; G01R 31/06

(52) U.S. Cl. CPC G01R 31/027; G01R 31/06

(57) ABSTRACT

According to an embodiment of a power network device, the device includes a computer configured to estimate a plurality of parameters internal to a transformer, including estimating a turns ratio of the transformer. The computer performs the parameter estimation based on an equivalent circuit model of the transformer and current and voltage samples which correspond to current and voltage measurements taken at primary side and secondary side terminals of the transformer. The computer indicates when one or more of the estimated parameters deviates from a nominal value by more than a predetermined amount. The computer can be part of an intelligent electronic device configured to acquire analog or digital signals representing the primary side and secondary side current and voltage measurements, or located remotely from the intelligent electronic device e.g. in the control room or substation controller.

### TECHNICAL FIELD

The instant application relates to transformer parameter estimation, and more particularly to transformer parameter estimation using terminal measurements.

### BACKGROUND

Transformer failures can cause major utility service interruptions, and it is often difficult to quickly replace a faulty transformer. The lead time to manufacture a large power transformer can take from 6 to 20 months. Thus, a better understanding about the state of health of the transformer and its fundamental parameters can aid utility companies in better planning and managing contingencies associated with aging and failure of transformers.

Currently, transformer health estimation uses two major approaches: direct measurement and model based. With direct measurement, representative parameters are measured by specially designed sensors or acquisition procedures, such as dissolved gas analysis, degree of polymerization testing and partial discharge monitoring, etc. Such techniques can estimate the transformer condition. However, the installation costs for on-line monitoring devices motivate less expensive approaches.

Model based approaches use a system identification technique to construct the transformer model based on terminal measurements. Several off-line modeling processes have been developed. However, an on-line method for monitoring the state of the in-service transformer is highly desired within the industry.

From a practical perspective, the life of a transformer is defined by the life of its insulation. The weakest link in the electrical insulation of the windings is the paper at the hot-spot location. The insulating paper is expected to degrade faster in this region.

In general, the health of a transformer can be indexed by a set of parameters, such as oxygen, moisture, acidity, temperature, etc. Insulation failures have been shown to be the leading cause of failure. Continuous online monitoring of the oil temperature with a thermal model of the transformer can give an estimation of the loss of life due to overheating.

Several model based online monitoring attempts have been made in the last several years. However, these proposed techniques are based on an equivalent circuit model of the transformer in which all parameters are referred to one side of the transformer. The problem with this type of approach is that, without knowing the transformer turns ratio, the referred measurements cannot be calculated. For tap-changing transformers, the turns ratio is a dynamic variable due to the normal tap changing operation and abnormal fault events. Thus, conventional online monitoring approaches only work on the equivalent circuit and assume the turns ratio is fixed and known a priori.

An effective online model based technique for estimating transformer condition based on real-time terminal measurements is highly desirable.

### SUMMARY

According to an embodiment of a method of transformer parameter estimation, the method comprises: receiving current and voltage samples which correspond to current and voltage measurements taken at primary side and secondary side terminals of a transformer; estimating a plurality of parameters internal to the transformer, including estimating a turns ratio of the transformer, based on an equivalent circuit model of the transformer and the current and voltage samples; and indicating when one or more of the estimated parameters deviates from a nominal value by more than a predetermined amount.

According to an embodiment of a power network device, the power network device comprises a computer configured to estimate a plurality of parameters internal to a transformer, including estimating a turns ratio of the transformer, based on an equivalent circuit model of the transformer and current and voltage samples which correspond to current and voltage measurements taken at primary side and secondary side terminals of the transformer. The computer is further configured to indicate when one or more of the estimated parameters deviates from a nominal value by more than a predetermined amount.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 illustrates a block diagram of an embodiment of a power network and a computer for estimating the transformer parameters.

FIG. 2 illustrates an embodiment of a transformer parameter estimation method.

FIG. 3 illustrates a circuit schematic of an exemplary equivalent circuit model of a transformer used in estimating the transformer parameters.

FIG. 4A shows a waveform diagram of input data for a least squares process used in estimating parameters of a transformer.

FIG. 4B shows a waveform diagram of input data for a least squares window process used in estimating parameters of a transformer.

FIG. 5 shows waveform diagrams of two-terminal (primary side and secondary side) voltage and current measurements applied to a transformer model for estimating the transformer parameters.

FIG. 6 shows waveform diagrams of the parameter estimation results based on the two-terminal (primary side and secondary side) voltage and current measurements of FIG. 5, for a first sampling rate scenario.

FIG. 7 shows waveform diagrams of the parameter estimation results based on the two-terminal (primary side and secondary side) voltage and current measurements of FIG. 5, for a second sampling rate scenario.

### DETAILED DESCRIPTION

Described next are embodiments in which a hybrid model based online technique is provided for estimating parameters of a transformer including turns ratio, series winding resistance, series leakage inductance, shunt magnetizing inductance and shunt core loss resistance. The techniques described herein do not require transformer outage and/or specialty sensors. Instead, an equivalent circuit model of the transformer is utilized along with voltage and current samples from both terminals of the transformer to estimate transformer parameters in less than a cycle. Also, the turns ratio of the transformer is treated as an unknown variable in the estimation process. The parameter estimation formulation can be solved using any standard approach that yields an approximate solution of an overdetermined system, such as the least squares method, the least squares window method, the recursive least squares method, etc.

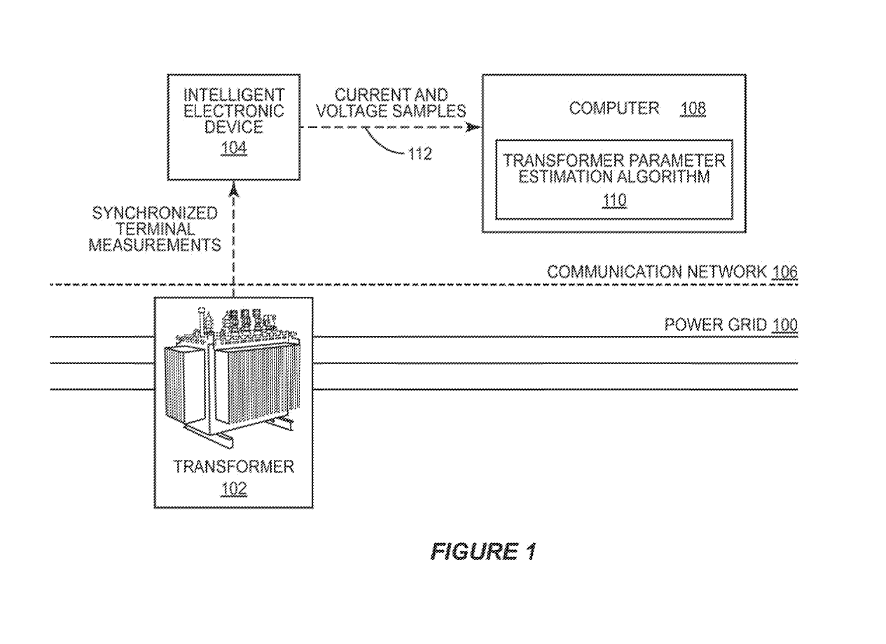

FIG. 1 illustrates an example of a power network that includes a power grid 100, transformers 102 and Intelligent Electronic Devices (IEDs) 104 connected to each transformer 102. A single transformer 102 and IED 104 are shown in FIG. 1 for ease of illustration only. The IED 104 is a microprocessor-based controller which receives analog or digital signals (‘Synchronized Terminal Measurements’) from voltage and current instrument transformers or sensors (not shown) installed on the terminals of the transformer 102. If the terminal measurement signals are analog, the IED 104 has an internal analog-to-digital and DSP (digital signal processing) circuitry for digitizing the data. If the terminal measurement signals are delivered as digital signals by way of for example IEC61850 merging units, the IED 104 can directly use the digital data.

In each case, the IED 104 acquires two-terminal (primary and secondary) synchronized voltage and current measurements which can be readily retrieved from the transformer 102 and provided via a communication network 106. The IED 104 converts the analog voltage and current measurements into current and voltage samples (‘Current and Voltage Samples’) used by a computer 108 to estimate parameters of the transformer 102 such as turns ratio, series winding resistance, series leakage inductance, shunt magnetizing inductance and shunt core loss resistance. The computer 108 includes circuitry such as memory and a processor for implementing a transformer parameter estimation algorithm 110 designed to estimate the transformer parameters based on an equivalent circuit model of the transformer 102 and the current and voltage samples provided by the IED 104.

The computer 108 can be part of the IED 104 or disposed remotely from the IED 104. For example, the computer 108 can be a control room computer for the power network or a substation computer (controller). According to remotely located embodiment, the computer 108 receives current and voltage samples from the IED 104 over a communication link 112. That is, the IED 104 receives primary and secondary side voltage and current measurements, and stores them in a preferred standard format e.g. COMTRADE. The synchronized two terminal voltage and current measurements can be transferred over the communication link 112 to a substation or control room computer. The transformer parameter estimation algorithm 110 can be run on a substation-hardened PC, or within a control room environment. Alternatively, the transformer parameter estimation algorithm 110 can be embedded into the protection and control IED 104 if the IED 104 satisfies the basic computational requirements of the algorithm.

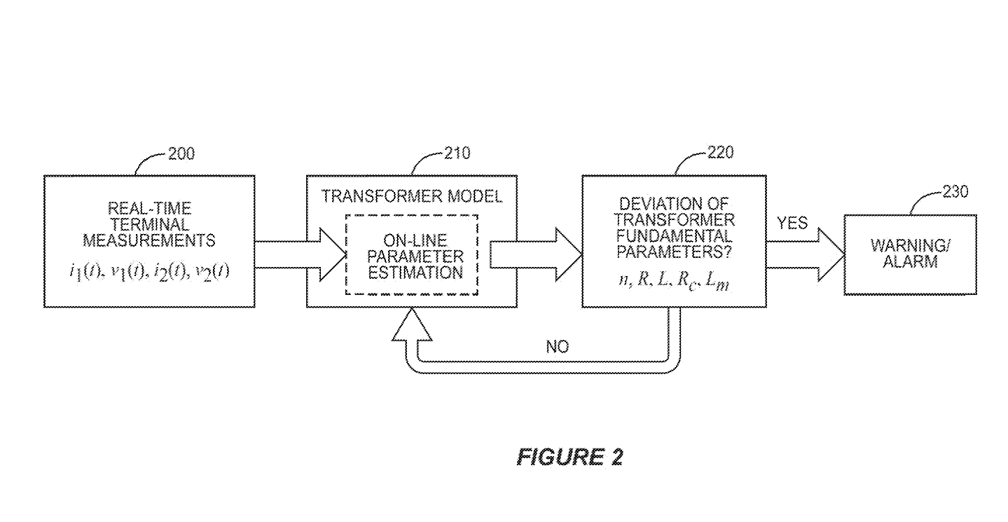

FIG. 2 illustrates an embodiment of the transformer parameter estimation method executed by the computer 108. The data input (Block 200) to the transformer parameter estimation algorithm 110 implemented by the computer 108 corresponds to a sampled version of the primary side (denoted by subscript ‘1’) and secondary side (denoted by subscript ‘2’) current and voltage terminal signals v₁(t), i₁(t), v₂(t) and i₂(t) measured at both sides of the transformer 102. The transformer model used by the transformer parameter estimation algorithm 110 is an equivalent circuit model of the transformer 102 which mimics the dynamic characteristic of the transformer 102. In one embodiment, the model is a transient model developed to evaluate the accuracy of the parameter estimation algorithm 110 in real-time. The structure of the model is fixed for the corresponding transformer 102. However, the parameters of the model are estimated using real-time measurements.

Based on the equivalent circuit model of the transformer 102 and the current and voltage samples input to the transformer parameter estimation algorithm 110, the algorithm 110 estimates transformer parameters including the turns ratio (n), series winding resistance (R), series leakage inductance (L), shunt magnetizing inductance (Lₘ) and shunt core loss resistance (R_{c}) (Block 210). The computer 108 determines whether one or more of the estimated parameters deviates from a nominal value by more than a predetermined amount (Block 220). If a deviation is detected (‘Yes’), the transformer 102 may be faulty or the real-time transformer measurements may not be correct or accurate. In either case, the computer 108 can take corrective action. For example, the computer 108 can generate a warning or alarm signal which indicates that the transformer 102 is faulty or the real-time transformer measurements are problematic (Block 230). If no deviation is detected (‘No’), the computer 108 continues to estimate the transformer parameters based on the equivalent circuit model of the transformer 102 and newly received current and voltage samples which correspond to real-time current and voltage measurements taken at the primary side and secondary side terminals of the transformer 102.

The computer 108 also can calculate a voltage or current output estimate for the transformer 102 based on the equivalent circuit model of the transformer 102 and the estimated parameters, and determine an estimation error based on the difference between the calculated voltage or current output estimate and the corresponding measured voltage or current sample. For example, the output of the transformer (e.g., secondary side voltage) 102 can be calculated based on the model. The actual output (measurement) data from the transformer 102 is also available from the IED 104. By subtracting the estimated output from the actual output measurement, the estimation error of the transformer model can be acquired. By tuning the transformer parameter estimate through a regression algorithm such as least squares, least squares window, recursive least squares, etc., the estimation error can be reduced to an acceptable level. This can be used as a calibration method. Once the calibration is over, the estimation error can be used for diagnostics purposes. For example, a deviation from a maximum estimation error can raise an alarm.

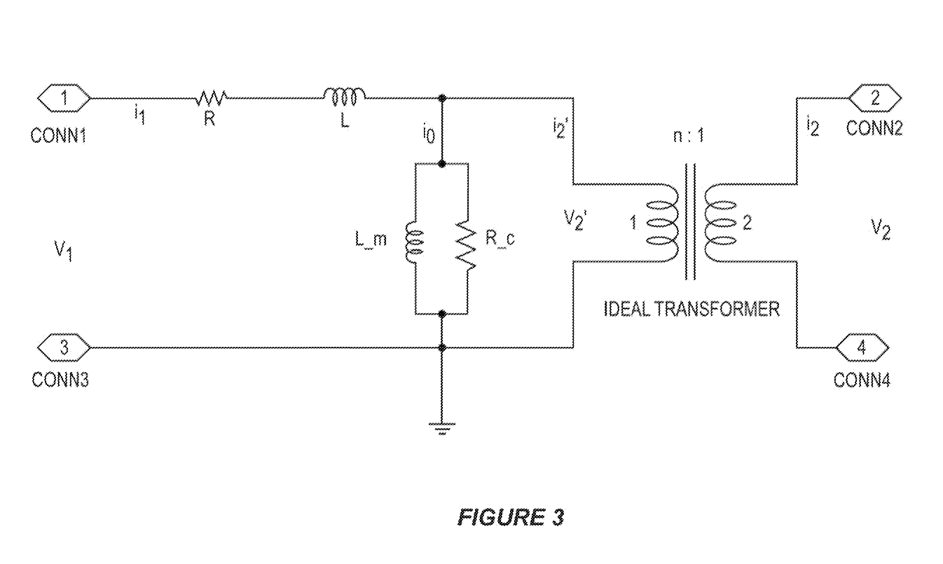

FIG. 3 illustrates a schematic of an exemplary equivalent circuit model of the transformer 102, for use in estimating the transformer parameters according to the techniques described herein. The transformer 102 can be modeled as an ideal transformer having an unknown turns ratio (n). Other unknown transformer parameters being modeled include series winding resistance (R), series leakage inductance (L), shunt magnetizing inductance (Lm) and shunt core loss resistance (Rc). The IED 104 or other type of power network device provides current and voltage samples which correspond to synchronized current and voltage measurements taken at the primary side terminals (Conn1, Conn3) and secondary side terminals (Conn2, Conn4) of the transformer 102 being modeled. The primary side current and voltage measurements are denoted i₁ and v₁, respectively. The secondary side current and voltage measurements are denoted i₂ and v₂, respectively. Since the current and voltage samples are communicated as discrete values in time, a discrete-time model can be used to represent the transformer dynamics.

An objective of the parameter estimation process is to reconstruct the parameters of the transformer model based on the transformer input and output measurements. Given the function:

y=Hx+v, (1)

where x is unknown, j by 1 is a vector, y is an m by 1 measurement vector, H is an m by j measurement matrix and v is an m by 1 measurement noise vector. To mitigate noise effects, several options are available for the estimation process.

The least squares estimation process is the simplest approach. By defining as the estimation of x, the estimation error can be represented as:

ε=y−H\hat{x}, (2)

To minimize the estimation error ε, a cost function can be defined as:

J(\hat{x})=ε^{T}ε, (3)

where the superscript T denotes the transposition of the error vector. When the partial derivative equals zero, J reaches its minimum, where:

\hat{x}=(H^{T}H)⁻¹H^{T}y (4)

The difference between the least squares estimation process and the least squares widow estimation process is the way in which input data is handled.

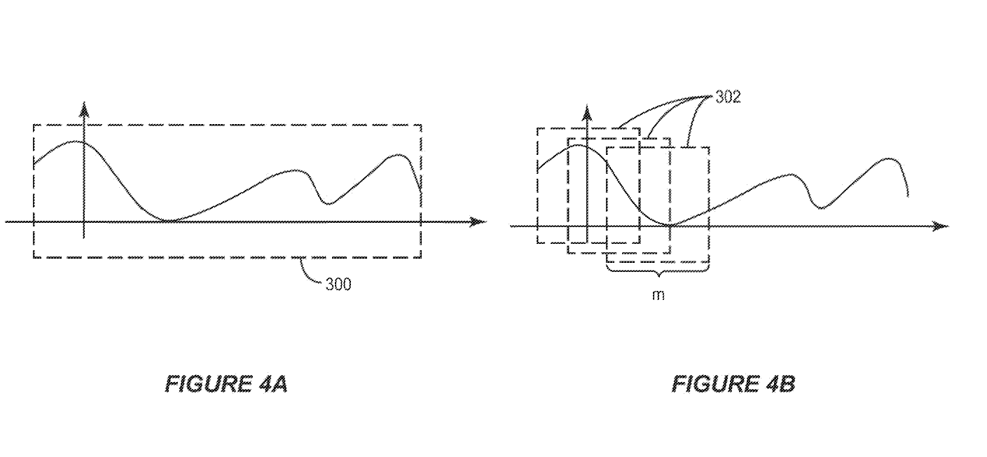

FIG. 4A shows the input data for the least squares estimation process, and FIG. 4B shows the input data for the least squares widow estimation process. As shown in FIG. 4A, the least squares method takes an entire set 300 of the digitized current and voltage samples and calculates the estimated parameters a single time for the entire set 300. As shown in FIG. 4B, the least squares widow method generates one set 302 of the estimated parameters for each window size m of the corresponding set 302 of current and voltage samples. The least squares widow method performs estimation based on a sliding window, resulting in multiple sets 302 of estimation results. However, there is no difference with the least squares method in the estimation algorithm.

The recursive least squares algorithm is iterative in that it updates the estimation results based on new incoming measurement data. That is, one set of estimated parameters is generated for each sampling time instance for the current and voltage samples. The current set of estimated transformer parameters can be influenced by one or more of the previously generated sets of the estimated parameters if desired.

The classical Kalman filter is a variation of the recursive least squares method where in addition to the measurement relationship described in equation (5), the system also has dynamic characteristics (normally linear system). The input-output function is:

y(t)=H(t)x(t)+v(t) (5)

For each iteration, the Kalman gain, which is a j by m matrix, can be calculated as given by:

K(t)=P(t−1)H(t)^{T}(H(t)P(t−1)H(t)^{T}+r(t))⁻¹, (6)

where r is an m by m matrix of measurement noise. The covariance matrix P is a j by j matrix as follows:

P(t)=(I−K(t)H(t))P(t−1), (7)

where I is a j by j identity matrix and the new estimation value is:

\hat{x}(t)=\hat{x}(t−1)+K(t)(y(t)−H(t)\hat{x}(t−1)). (8)

The least squares method does not accumulate any information over time i.e. each estimated result is independent from each other. However, the calculation takes a relatively long time. The results normally have some delay which depends on the size of the data window. The recursive least squares method minimizes the aggregated variance of the estimation errors over time. The delay of recursive least squares method is one data point or one iteration. This means right after it reads one voltage and current measurements from both the primary and secondary set, it can estimates all the five parameters. The result of the recursive least squares method is relatively accurate upon reaching steady state.

Returning to the equivalent circuit model of the transformer 102 shown in FIG. 3, a common issue in the state of the art is that i₂′ and v₂′ are used as inputs to conventional estimation algorithms. However, without knowing the turns ratio n, i₂′ and v₂′ are practically unavailable. To incorporate the turns ratio n into the transformer parameter estimation algorithm 110, v₂′ can be expressed as:

v₂′(t)=nv₂(t). (9)

and then the transformer state equations can be expressed as:

$$\begin{matrix}{v}_{1} ( t ) = {nv}_{2} ( t ) + {Ri}_{1} ( t ) + L \frac{d {i}_{1} ( t )}{d t} , & ( 10 ) \\ {v}_{2} ( t ) = \frac{{L}_{m}}{n} \frac{d {i}_{0} ( t )}{d t} - \frac{{L}_{m}}{{R}_{c}} \frac{d {v}_{2} ( t )}{d t} , & ( 11 )\end{matrix}$$

where v₁(t), i₁(t), v₂(t) and i₂(t) are IED measurements. Measurements i₁(t), v₁(t) are the current and voltage, respectively, on the primary side. Measurements i₂(t), v₂(t) are the current and voltage, respectively, on the secondary side. Current i₂′(t) and volatge v₂′(t) are the secondary side current and voltage, respectively, referred to the primary side but not directly available in the practical case. Current i₀ is the magnetizing current and i₀(t)=i₁(t)−i₂′(t). The model parameters to be estimated are: n (turns ratio), R (series winding resistance), L (series leakage inductance), Lₘ (shunt magnetizing inductance) and R_{c} (shunt core loss resistance).

For the case of m v₁(t), i₁(t), v₂(t) and i₂(t) measurements, equation (10) can be written in the following matrix form:

$$[ \begin{matrix}{v}_{1} ( 1 ) \\ {v}_{1} ( 2 ) \\ ⋮ \\ {v}_{1} ( m )\end{matrix} ] = [ \begin{matrix}{v}_{2} ( 1 ) & {i}_{1} ( 1 ) & {\dot{i}}_{1} ( 1 ) \\ {v}_{2} ( 2 ) & {i}_{1} ( 2 ) & {\dot{i}}_{1} ( 2 ) \\ ⋮ & ⋮ & ⋮ \\ {v}_{2} ( m ) & {i}_{1} ( m ) & {\dot{i}}_{1} ( m )\end{matrix} ] [ \begin{matrix}n \\ R \\ L\end{matrix} ] \qquad ( 12 )$$

This matrix form can be expressed in least squares form as given by:

$$\begin{matrix}y = {[ {v}_{1} ( 1 ) {v}_{1} ( 2 ) ⋯ {v}_{1} ( m ) ]}^{T} , & ( 13 ) \\ H = [ \begin{matrix}{v}_{2} ( 1 ) & {i}_{1} ( 1 ) & {\dot{i}}_{1} ( 1 ) \\ {v}_{2} ( 2 ) & {i}_{1} ( 2 ) & {\dot{i}}_{1} ( 2 ) \\ ⋮ & ⋮ & ⋮ \\ {v}_{2} ( m ) & {i}_{1} ( m ) & {\dot{i}}_{1} ( m )\end{matrix} ] , & ( 14 ) \\ x = {[ n , R , L ]}^{T} . & ( 15 )\end{matrix}$$

The approximated derivative of i₁ at kth step can be calculated as given by:

\dot{i}₁(k)≈(i₁(k+1)−i₁(k−1))/(2×step size) (16)

Then n, R and L can be estimated. The value m has a lower boundary, which will be discussed later herein with regard to the window size analysis.

In a similar manner, equation (11) can be written as:

$$\begin{matrix}[ \begin{matrix}{v}_{1} ( 1 ) \\ {v}_{1} ( 2 ) \\ ⋮ \\ {v}_{1} ( m )\end{matrix} ] = [ \begin{matrix}{\dot{i}}_{0} ( 1 ) & {\dot{v}}_{2} ( 1 ) \\ {\dot{i}}_{0} ( 2 ) & {\dot{v}}_{2} ( 2 ) \\ ⋮ & ⋮ \\ {\dot{i}}_{0} ( m ) & {\dot{v}}_{2} ( m )\end{matrix} ] [ \begin{matrix}\frac{{L}_{m}}{n} \\ \frac{{L}_{m}}{{R}_{c}}\end{matrix} ] , & ( 17 ) \\ y = {[ {v}_{2} ( 1 ) {v}_{2} ( 2 ) ⋯ {v}_{2} ( m ) ]}^{T} , & ( 18 ) \\ H = [ \begin{matrix}{\dot{i}}_{0} ( 1 ) & {\dot{v}}_{2} ( 1 ) \\ {\dot{i}}_{0} ( 2 ) & {\dot{v}}_{2} ( 2 ) \\ ⋮ & ⋮ \\ {\dot{i}}_{0} ( m ) & {\dot{v}}_{2} ( m )\end{matrix} ] , & ( 19 ) \\ x = {[ \frac{{L}_{m}}{n} , \frac{{L}_{m}}{{R}_{c}} ]}^{T} . & ( 20 )\end{matrix}$$

Since n is estimated from eq. (12), it is treated as known in eq. (20) and therefore only two unknowns Lₘ and R_{c} are estimated based on eq. (17).

For the least squares method, the entire data set 300 provides a single set of results as previously described herein. As such, this approach is not practical for dynamic system estimation.

For the least squares window method, the window size is defined by m. Once the algorithm receives the mth measurement, it can start to generate one set 302 of results. The result is delayed by m samples.

For the recursive least squares method, equations (5) to (8) are updated at every step, where t=1, 2, . . . k. For estimating n, R and L:

y(t)_{1×1}=v₁(t), (21)

H(t)_{1×3}=[v₂(t)i₁(t)\dot{i}₁(t)], (22)

K(t)_{3×1}=P(t−1)_{3×3}H(t)_{1×3}^{T}(H(t)_{1×3}P(t−1)_{3×3}H(t)_{1×3}^{T}+r(t)_{1×1})⁻¹, (23)

The updated covariance matrix is given by:

P(t)_{3×3}=(I_{3×3}−K(t)_{3×1}H(t)_{1×3})P(t−1)_{3×3}. (24)

and the new estimation value is:

\hat{x}(t)_{3×1}=\hat{x}(t−1)_{3×1}+K(t)_{3×1}(y(t)_{1×1}−H(t)_{1×3}\hat{x}(t−1)_{3×1}). (25)

Similarly, for estimating Lₘ and R_{c}:

y(t)_{1×1}=v₂(t), (26)

H(t)_{1×2}=[\dot{i}₀(t)v₂(t)], (27)

K(t)_{2×1}=P(t−1)_{2×2}H(t)_{1×2}^{T}(H(t)_{1×2}P(t−1)_{2×2}H(t)_{1×2}^{T}+r(t)_{1×1})⁻¹, (28)

and the updated covariance matrix is:

P(t)_{2×2}=(I_{2×2}−K(t)_{2×1}H(t)_{1×2})P(t−1)_{2×2}. (29)

The new estimation value is:

\hat{x}(t)_{2×1}=\hat{x}(t−1)_{2×1}+K(t)_{2×1}(y(t)_{1×1}−H(t)_{1×2}\hat{x}(t−1)_{2×1}). (30)

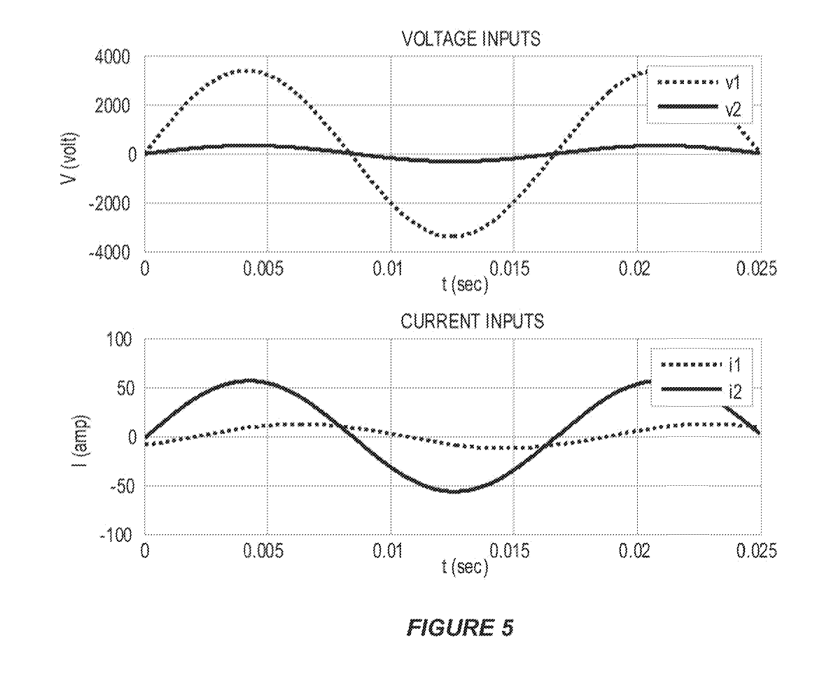

The recursive least squares method has a delay of only one iteration. Since it is a recursive algorithm, there is an initialization process before taking the first set of measurements. If there is no information about the transformer 102, the initialization of estimating n, R and L can be done by setting x(0)=[0 0 0]^{T} and P(0)=diag(1000, 1000, . . . 1000)ⱼ, where j depends on the size of x. The value of covariance matrix P indicates an uncertainty level associated with the current estimation, which is similar to the covariance matrix in a Kalman filter. However, some arbitrary positive numbers can be set as the initial values of P. In the following purely illustrative transformer parameter estimation example shown in FIGS. 5 and 6, 1000 has been used as the diagonal value of P(0).

FIG. 5 shows the two-terminal (primary side and secondary side) voltage and current measurements for the simulated transformer model. The total simulation time is 1.5 cycles, the sampling rate is 40 kHz and the number of data points per cycle is 666 in this example. The total number of data points for the entire 1.5 cycles is 1000. Measurements i₁(t), v₁(t) are the current and voltage, respectively, on the primary side and meausrements i₂(t), v₂(t) are the current and voltage, respectively, on the secondary side. The two-terminal voltage and current measurements are the inputs to the transformer parameter estimation algorithm 110 implemented by the computer 108.

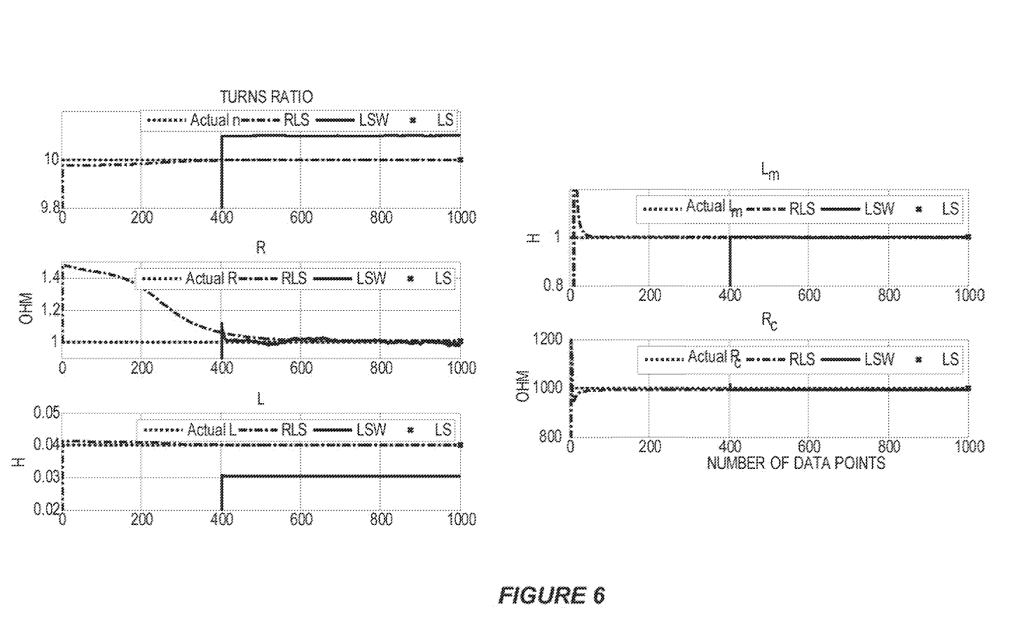

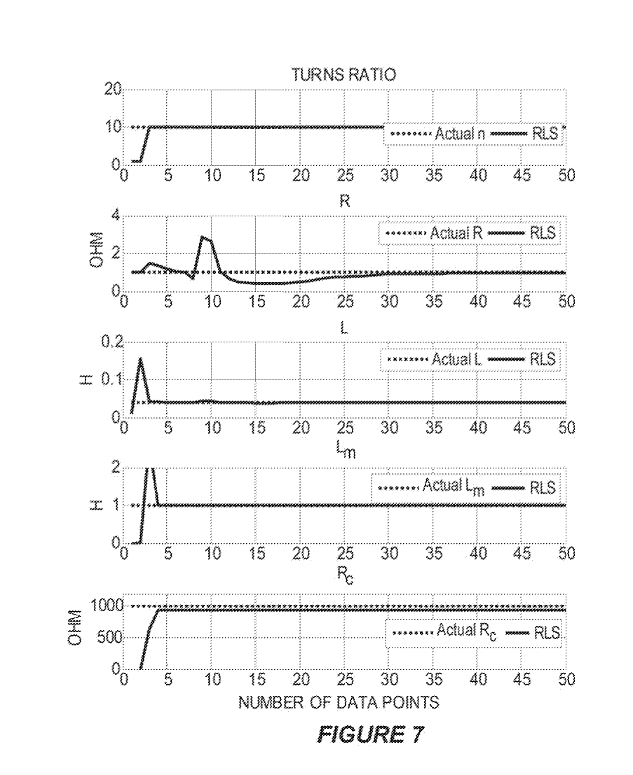

FIG. 6 shows the corresponding simulation results. The dotted line of each plot is the actual (known) parameter value. The dot-dash line of each plot represents the estimation results for the corresponding transformer parameter estimated by the recursive least squares (RLS) method. As can be seen in FIG. 6, the recursive least squares algorithm converges quickly on n (turns ratio), L (series leakage inductance), Lₘ (shunt magnetizing inductance) and R_{c} (shunt core loss resistance). The series winding resistance (R) takes more iterations (around one cycle) to converge. The solid line of each plot represents the estimation results for the corresponding transformer parameter estimated by the least squares widow (LSW) method. With an exemplary window size of 400, the first estimation is available at the 401st data point and it is not as accurate as the RLS results for parameters n (turns ratio) and L (series leakage inductance). The least squares (LS) method accumulates 1000 data points (1.5 cycles) before it outputs the estimation results which are relatively accurate. The initial simulation was done at a sampling rate of 40 kHz. After down-sampling from 40 kHz to 2 kHz, the original 1000 data points are reduced to 50. However, the RLS algorithm still converges within the same time as it does with the higher sampling rate. The parameter estimation results using RLS method for the down-sampled simulation are shown in FIG. 7. There are less data points available now for the same method, but the time they take to estimate the parameters are the same. The transformer parameter estimation algorithm 110 has been demonstrated to work with sampling rates as low as 2 kHz.

The transformer parameter estimation embodiments described herein estimate the transformer condition based on online terminal measurements. The parameter estimation process has a relatively fast response time in that the transformer parameter estimation algorithm 110 utilizes time-domain online terminal measurements and a dynamic equivalent circuit model of the transformer 102 that converges in one cycle ( 1/60 seconds), and eliminates the need for high-frequency specialty measurement devices. In addition, the estimation process treats the transformer turns ratio (n) as an unknown variable due to normal tap changing operations and abnormal fault events.

The estimation errors can be further reduced by using a weighted least squares algorithm. Also, the transformer parameter estimation algorithm 110 can be extended to three-phase transformers with different transformer configurations.

Terms such as “first”, “second”, and the like, are used to describe various elements, regions, sections, etc. and are not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A method of transformer parameter estimation, the method comprising:
receiving current and voltage samples which correspond to current and voltage measurements taken at primary side and secondary side terminals of a transformer;
estimating a plurality of parameters internal to the transformer, including estimating a turns ratio of the transformer, based on an equivalent circuit model of the transformer and the current and voltage samples; and
indicating when one or more of the estimated parameters deviates from a nominal value by more than a predetermined amount.

2. The method of claim 1, wherein:
the equivalent circuit model includes a first state equation and a second state equation;
the first state equation expresses primary side voltage of the transformer as a function of secondary side voltage of the transformer, primary side current of the transformer, series winding resistance of the transformer, series leakage inductance of the transformer, and the turns ratio; and
the second state equation expresses the secondary side voltage of the transformer as a function of secondary side voltage of the transformer, shunt magnetizing inductance of the transformer, shunt core loss resistance of the transformer, magnetizing current of the transformer, and the turns ratio.

3. The method of claim 2, wherein the turns ratio, the series winding resistance, the series leakage inductance, the shunt magnetizing inductance and the shunt core loss resistance are the plurality of parameters estimated based on the equivalent circuit model and the current and voltage samples.

4. The method of claim 3, wherein estimating the plurality of parameters based on the equivalent circuit model and the current and voltage samples comprises:
estimating the turns ratio, the series winding resistance and the series leakage inductance by applying a regression algorithm to the first state equation; and
estimating the shunt magnetizing inductance and the shunt core loss resistance by applying the regression algorithm to the second state equation, wherein the turns ratio estimated by applying the regression algorithm to the first state equation is treated as a known quantity when estimating the shunt magnetizing inductance and the shunt core loss resistance by applying the regression algorithm to the second state equation.

5. The method of claim 4, wherein the regression algorithm is a least squares algorithm which calculates the estimated parameters a single time for an entire set of the current and voltage samples.

6. The method of claim 4, wherein the regression algorithm is a least squares window algorithm which generates one set of the estimated parameters for each window size m of an entire set of current and voltage samples.

7. The method of claim 4, wherein the regression algorithm is a recursive least squares algorithm which generates one set of the estimated parameters for each sampling time instance for the current and voltage samples, and wherein the plurality of parameters are estimated based on one or more of the previously generated sets of the estimated parameters.

8. The method of claim 1, further comprising:
calculating a voltage or current output estimate for the transformer based on the equivalent circuit model and the estimated parameters; and
determining an estimation error based on the difference between the calculated voltage or current output estimate and the corresponding measured voltage or current sample.

9. A power network device, comprising:
a computer configured to estimate a plurality of parameters internal to a transformer, including estimating a turns ratio of the transformer, based on an equivalent circuit model of the transformer and current and voltage samples which correspond to current and voltage measurements taken at primary side and secondary side terminals of the transformer, and indicate when one or more of the estimated parameters deviates from a nominal value by more than a predetermined amount.

10. The power network device of claim 9, wherein:
the equivalent circuit model includes a first state equation and a second state equation;
the first state equation expresses primary side voltage of the transformer as a function of secondary side voltage of the transformer, primary side current of the transformer, series winding resistance of the transformer, series leakage inductance of the transformer, and the turns ratio; and
the second state equation expresses the secondary side voltage of the transformer as a function of secondary side voltage of the transformer, shunt magnetizing inductance of the transformer, shunt core loss resistance of the transformer, magnetizing current of the transformer, and the turns ratio.

11. The power network device of claim 10, wherein the turns ratio, the series winding resistance, the series leakage inductance, the shunt magnetizing inductance and the shunt core loss resistance are the plurality of parameters estimated by the computer based on the equivalent circuit model and the current and voltage samples.

12. The power network device of claim 11, wherein the computer is configured to estimate the turns ratio, the series winding resistance and the series leakage inductance by applying a regression algorithm to the first state equation, and estimate the shunt magnetizing inductance and the shunt core loss resistance by applying the regression algorithm to the second state equation, wherein the turns ratio estimated by applying the regression algorithm to the first state equation is treated as a known quantity when estimating the shunt magnetizing inductance and the shunt core loss resistance by applying the regression algorithm to the second state equation.

13. The power network device of claim 12, wherein the regression algorithm is a least squares algorithm which calculates the estimated parameters a single time for an entire set of the current and voltage samples.

14. The power network device of claim 12, wherein the regression algorithm is a least squares window algorithm which generates one set of the estimated parameters for each window size m of an entire set of current and voltage samples.

15. The power network device of claim 12, wherein the regression algorithm is a recursive least squares algorithm which generates one set of the estimated parameters for each sampling time instance for the current and voltage samples, and wherein the plurality of parameters are estimated based on one or more of the previously generated sets of the estimated parameters.

16. The power network device of claim 9, wherein the computer is configured to calculate a voltage or current output estimate for the transformer based on the equivalent circuit model and the estimated parameters, and determine an estimation error based on the difference between the calculated voltage or current output estimate and the corresponding measured voltage or current sample.

17. The power network device of claim 9, wherein the computer is part of an intelligent electronic device configured to acquire analog or digital signals representing voltage and current measurements from the primary side and secondary side terminals and provide the current and voltage samples used to estimate the plurality of parameters.

18. The power network device of claim 9, wherein the computer is disposed remotely from an intelligent electronic device configured to acquire analog or digital signals representing voltage and current measurements from the primary side and secondary side terminals and provide the current and voltage samples used to estimate the plurality of parameters, and wherein the computer is configured to receive the current and voltage samples from the intelligent electronic device over a communication link.
